(19) United States
(12) Patent Application Publication
(10) Pub. No.: US 2026/0096466 A1
(43) Pub. Date: Apr. 2, 2026

(54) SEMICONDUCTOR PACKAGE INCLUDING A MOLDED UNDERFILL STRUCTURE, AND A PACKAGE SUBSTRATE

(71) Applicant: SK hynix Inc., Icheon-si Gyeonggi-do (KR)

(72) Inventors: Hyun Chul SEO, Icheon-si Gyeonggi-do (KR); Jun Shin LEE, Icheon-si Gyeonggi-do (KR)

(73) Assignee: SK hynix Inc., Icheon-si Gyeonggi-do (KR)

(21) Appl. No.: 19/233,490

(22) Filed: Jun. 10, 2025

(30) Foreign Application Priority Data
Sep. 27, 2024 (KR) 10-2024-0131879
Jan. 20, 2025 (KR) 10-2025-0007949

(51) Int. Cl. H01L 23/31; H01L 23/00; H01L 23/13; H01L 23/498; H01L 23/538; H01L 25/065

(52) U.S. Cl. CPC H10W 74/111; H10W 70/611; H10W 70/65; H10W 70/68; H10W 90/00; H10W 90/701; H10W 90/724

(57) ABSTRACT

A semiconductor package includes a package substrate including a body layer and a first insulating layer disposed on the body layer; first and second semiconductor chips mounted on the package substrate; and a molding layer filling the spaces between the package substrate and the first and second semiconductor chips, and surrounding the first and second semiconductor chips, wherein the body layer includes a first chip overlapping region that vertically overlaps the first semiconductor chip, a second chip overlapping region that vertically overlaps the second semiconductor chip and an intermediate region between the first chip overlapping region and the second chip overlapping region, and wherein the first insulating layer includes a first opening that exposes the intermediate region, an edge section of the first chip overlapping region abutting the intermediate region and an edge section of the second chip overlapping region abutting the intermediate region.

### CROSS-REFERENCE TO RELATED APPLICATION

The present application claims priority under 35 U.S.C. § 119(a) to Korean Patent Application Nos. 10-2024-0131879 and 10-2025-0007949, filed in the Korean Intellectual Property Office on Sep. 27, 2024 and Jan. 20, 2025, respectively, the entire contents of which applications are incorporated herein by reference.

### BACKGROUND

### 1. Technical Field

Embodiments of the present disclosure generally relate to a semiconductor package, and more particularly, to a semiconductor package including a molded underfill structure, and a package substrate.

### 2. Related Art

A flip chip package includes a package substrate, a semiconductor chip that is bonded onto the package substrate by the medium of bumps, an underfill that fills the space between the package substrate and the semiconductor chip, and a molding layer that surrounds the semiconductor chip.

The underfill serves to provide a mechanical coupling between the package substrate and the semiconductor chip and alleviates stress caused by a difference in the coefficient of thermal expansion (CTE) between the package substrate and the semiconductor chip. Depending on the type of underfill method chosen, the underfill may be either a capillary underfill (CUF) method or a molded underfill (MUF) method.

The capillary underfill (CUF) method includes injecting an underfill material between the package substrate and the semiconductor chip by utilizing the capillary phenomenon. A process of surrounding the semiconductor chip and the package substrate injected with the underfill material with a molding material may be further applied. The molded underfill (MUF) method includes filling a molding material between the package substrate and the semiconductor chip in a molding process for forming a molding layer without a separate underfill process.

### SUMMARY

In an embodiment, a semiconductor package may include: a package substrate including a body layer and a first insulating layer that is disposed on the body layer; a first semiconductor chip mounted on the package substrate by a first bump; a second semiconductor chip mounted on the package substrate a second bump; and a molding layer filling the space between the package substrate and the first semiconductor chip and the space between the package substrate and the second semiconductor chip, and surrounding the first and second semiconductor chips, wherein the body layer includes a first chip overlapping region that vertically overlaps the first semiconductor chip, a second chip overlapping region that vertically overlaps the second semiconductor chip and an intermediate region between the first chip overlapping region and the second chip overlapping region, and wherein the first insulating layer includes a first opening that exposes the intermediate region, an edge section of the first chip overlapping region abutting the intermediate region and an edge section of the second chip overlapping region abutting the intermediate region.

In an embodiment, a package substrate may include: a body layer; and a first insulating layer disposed on the body layer, wherein the body layer includes first and second chip overlapping regions, and an intermediate region, wherein the second chip overlapping region is disposed next to the first chip overlapping region in a first horizontal direction, and the intermediate region is disposed between the first chip overlapping region and the second chip overlapping region, and wherein the first insulating layer includes a first opening that exposes the intermediate region and an edge of the first chip overlapping region and an edge of the second chip overlapping region that abut the intermediate region.

### BRIEF DESCRIPTION OF THE DRAWINGS

FIG. 1 is a plan view of a semiconductor package according to an embodiment of the present disclosure.

FIG. 2 is a plan view schematically illustrating the body layer of a package substrate of FIG. 1 according to an embodiment of the present disclosure.

FIG. 3 is a cross-sectional view taken along a line A-A′ of FIG. 1 according to an embodiment of the present disclosure.

FIG. 4 is a cross-sectional view taken along a line B-B′ of FIG. 1 according to an embodiment of the present disclosure.

FIG. 5 is a cross-sectional view taken along a line C-C′ of FIG. 1 according to an embodiment of the present disclosure.

FIG. 6 is a cross-sectional view taken along a line D-D′ of FIG. 1 according to an embodiment of the present disclosure.

FIG. 7 is a cross-sectional view taken along a line E-E′ of FIG. 1 according to an embodiment of the present disclosure.

FIG. 8 is a plan view of a semiconductor package according to an embodiment of the present disclosure.

FIG. 9 is a cross-sectional view taken along a line F-F′ of FIG. 8 according to an embodiment of the present disclosure.

FIG. 10 is a cross-sectional view taken along a line G-G′ of FIG. 8 according to an embodiment of the present disclosure.

FIG. 11 is a plan view of a semiconductor package according to an embodiment of the present disclosure.

FIG. 12 is a plan view schematically illustrating the body layer of a package substrate of FIG. 11.

FIG. 13 is a cross-sectional view taken along a line H-H′ of FIG. 11 according to an embodiment of the present disclosure.

FIG. 14 is a cross-sectional view taken along a line I-I′ of FIG. 11 according to an embodiment of the present disclosure.

FIG. 15 is a cross-sectional view taken along a line J-J′ of FIG. 11 according to an embodiment of the present disclosure.

FIG. 16 is a cross-sectional view taken along a line K-K′ of FIG. 11 according to an embodiment of the present disclosure.

FIG. 17 is a cross-sectional view taken along a line L-L′ of FIG. 11 according to an embodiment of the present disclosure.

FIG. 18 is a cross-sectional view taken along a line M-M′ of FIG. 11 according to an embodiment of the present disclosure.

FIG. 19 is a plan view illustrating a molded underfill process related with the present disclosure.

FIG. 20 is a cross-sectional view taken along a line N-N′ of FIG. 19 according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

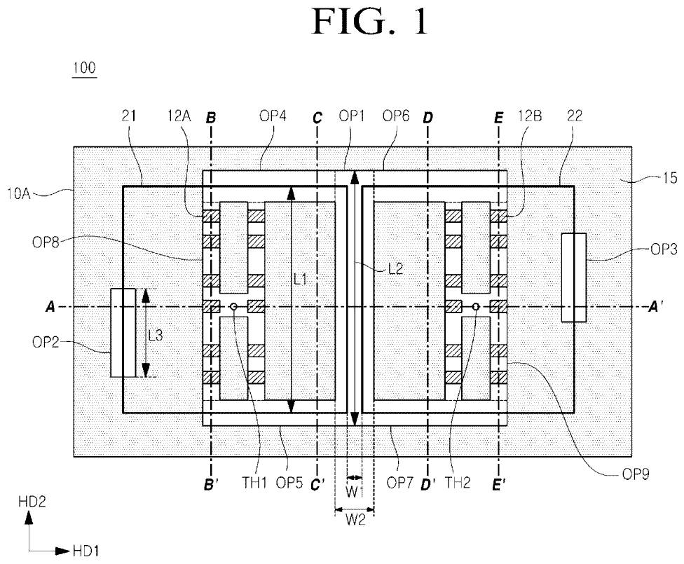

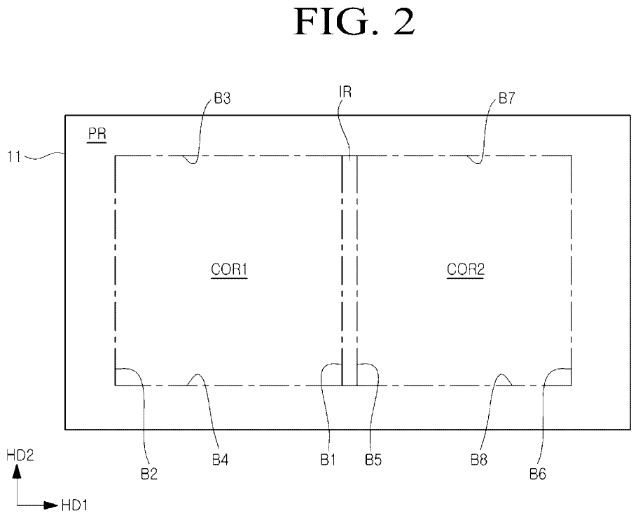

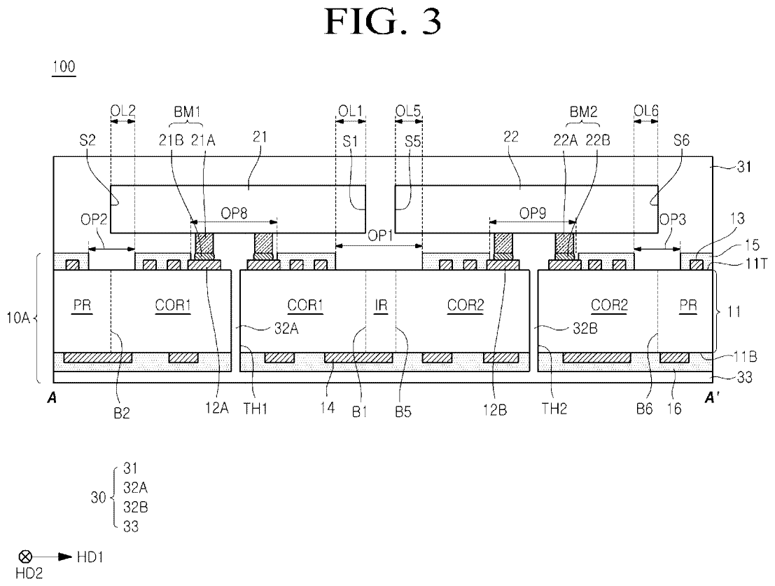

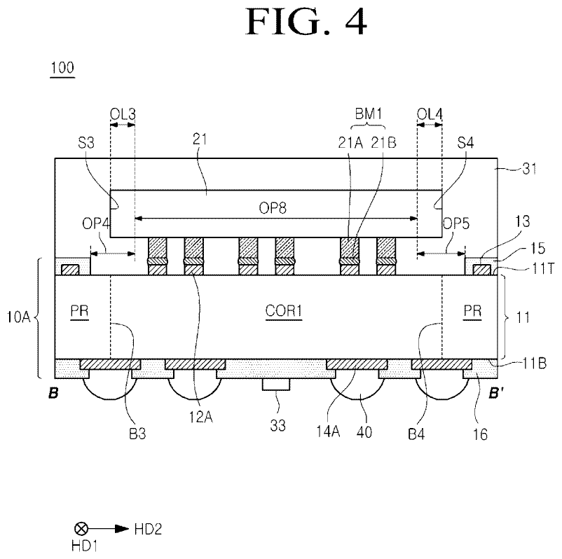

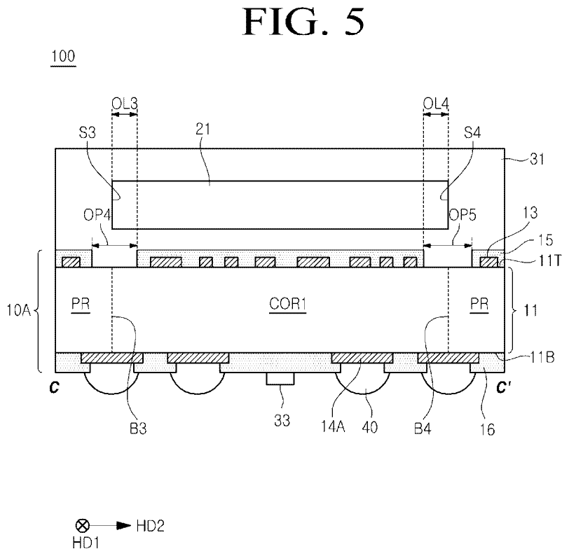

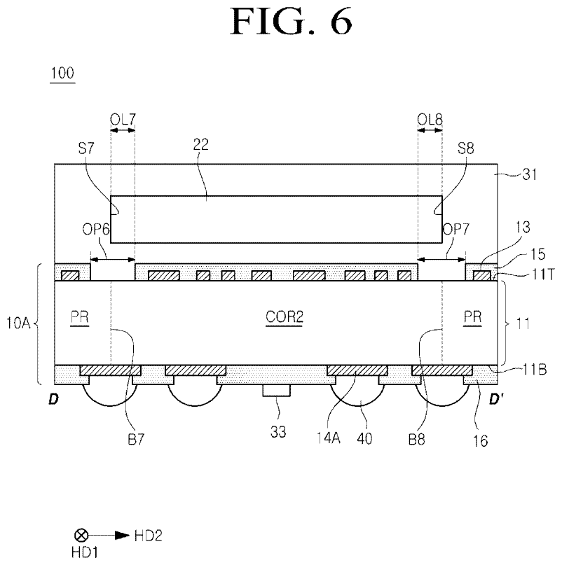

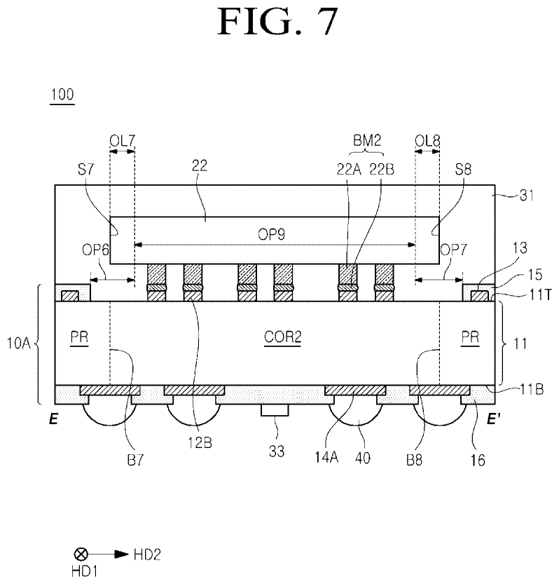

FIG. 1 is a plan view of a semiconductor package according to an embodiment of the present disclosure, FIG. 2 is a plan view schematically illustrating the body layer of a package substrate of FIG. 1, FIG. 3 is a cross-sectional view taken along a line A-A′ of FIG. 1, FIG. 4 is a cross-sectional view taken along a line B-B′ of FIG. 1, FIG. 5 is a cross-sectional view taken along a line C-C′ of FIG. 1, FIG. 6 is a cross-sectional view taken along a line D-D′ of FIG. 1, and FIG. 7 is a cross-sectional view taken along a line E-E′ of FIG. 1.

Referring to FIG. 1 to FIG. 7, a semiconductor package 100 according to an embodiment of the present disclosure includes a package substrate 10A, first and second semiconductor chips 21 and 22, a molding layer 30 and external connection terminals 40. In order to facilitate understanding, illustration of the molding layer 30 is omitted in FIG. 1.

The first and second semiconductor chips 21 and 22 are mounted on the package substrate 10A. The first semiconductor chip 21 is bonded onto the package substrate 10A by the medium of first bumps BM1. The first bump BM1 includes a first metal layer 21A and a first solder layer 21B. The second semiconductor chip 22 is bonded onto the package substrate 10A by the medium of second bumps BM2. The second bump BM2 includes a second metal layer 22A and a second solder layer 22B. The first semiconductor chip 21 is disposed next to the second semiconductor chip 22 in a first horizontal direction HD1. The first semiconductor chip 21 and the second semiconductor chip 22 are disposed to be spaced apart from each other.

The package substrate 10A may include a circuit and/or wiring structure (not illustrated) for electrically connecting the first and second semiconductor chips 21 and 22 to the external connection terminals 40. The package substrate 10A may include a printed circuit board (PCB), an interposer or a redistribution layer.

The package substrate 10A includes a body layer 11, first bump bonding pads 12A, second bump bonding pads 12B, first metal patterns 13, second metal patterns 14, a first insulating layer 15, and a second insulating layer 16.

The body layer 11 includes a first chip overlapping region COR1 that vertically overlaps the first semiconductor chip 21, a second chip overlapping region COR2 that vertically overlaps the second semiconductor chip 22, an intermediate region IR between the first chip overlapping region COR1 and the second chip overlapping region COR2, and a peripheral region PR. The first chip overlapping region COR1 and the second chip overlapping region COR2 are disposed on both sides, respectively, of the intermediate region IR in the first horizontal direction HD1. The peripheral region PR is a region that surrounds the first and second chip overlapping regions COR1 and COR2 and the intermediate region IR.

The first semiconductor chip 21 includes a first side surface S1 and a second side surface S2 that face each other in the first horizontal direction HD1, and a third side surface S3 and a fourth side surface S4 that face each other in a second horizontal direction HD2. The first horizontal direction HD1 and the second horizontal direction HD2 are two directions that are parallel to a top surface 11T of the body layer 11 and are perpendicular to each other.

First, second, third and fourth boundaries B1, B2, B3 and B4 of the first chip overlapping region COR1 of the body layer 11 correspond to the first, second, third and fourth side surfaces S1, S2, S3 and S4, respectively, of the first semiconductor chip 21. The first boundary B1 of the first chip overlapping region COR1 abuts the intermediate region IR, and the second, third and fourth boundaries B2, B3 and B4 of the first chip overlapping region COR1 abut the peripheral region PR.

The second semiconductor chip 22 includes a fifth side surface S5 and a sixth side surface S6 that face each other in the first horizontal direction HD1, and a seventh side surface S7 and an eighth side surface S8 that face each other in the second horizontal direction HD2. Fifth, sixth, seventh and eighth boundaries B5, B6, B7 and B8 of the second chip overlapping region COR2 of the body layer 11 correspond to the fifth, sixth, seventh and eighth side surfaces S5, S6, S7 and S8, respectively, of the second semiconductor chip 22. The fifth boundary B5 of the second chip overlapping region COR2 abuts the intermediate region IR, and the sixth, seventh and eighth boundaries B6, B7 and B8 of the second chip overlapping region COR2 abut the peripheral region PR.

The first bump bonding pads 12A and the second bump bonding pads 12B are disposed on the top surface 11T of the body layer 11. The first bump bonding pads 12A are disposed on the first chip overlapping region COR1, and the second bump bonding pads 12B are disposed on the second chip overlapping region COR2. In the present embodiment, the first bump bonding pads 12A are disposed in two columns in the second horizontal direction HD2, and the second bump bonding pads 12B are disposed in two columns in the second horizontal direction HD2, but the present disclosure is not limited thereto. As the case may be, the disposition pattern of the first bump bonding pads 12A and the second bump bonding pads 12B may be changed.

The first insulating layer 15 is disposed on the top surface 11T of the body layer 11. The first insulating layer 15 may include a photosensitive solder resist (PSR).

The first insulating layer 15 includes first to ninth openings OP1 to OP9.

The first opening OP1 exposes the intermediate region IR, an edge section of the first chip overlapping region COR1 including the first boundary B1, and an edge section of the second chip overlapping region COR2 including the fifth boundary B5. The first opening OP1 vertically overlaps an edge section of the first semiconductor chip 21 including the first side surface S1. As illustrated in FIG. 3, the first opening OP1 overlaps the first semiconductor chip 21 by a first width OL1 in the first horizontal direction HD1. The first opening OP1 vertically overlaps an edge section of the second semiconductor chip 22 including the fifth side surface S5. As illustrated in FIG. 3, the first opening OP1 overlaps the second semiconductor chip 22 by a fifth width OL5 in the first horizontal direction HD1. Each of the first width OL1 and the fifth width OL5 may have a size of 20 μm (micrometers) or more.

The dimension in the first horizontal direction HD1 of the first opening OP1 is larger than the dimension in the first horizontal direction HD1 of the intermediate region IR. As illustrated in FIG. 1, the dimension in the first horizontal direction HD1 of the intermediate region IR has a size of W1, and the dimension in the first horizontal direction HD1 of the first opening OP1 has a size of W2 that is larger than W1. The dimension in the second horizontal direction HD2 of the first opening OP1 may be larger than the dimension in the second horizontal direction HD2 of the first chip overlapping region COR1 and the dimension in the second horizontal direction HD2 of the second chip overlapping region COR2. As illustrated in FIG. 1, the dimension in the second horizontal direction HD2 of the first chip overlapping region COR1 and the dimension in the second horizontal direction HD2 of the second chip overlapping region COR2 have a size of L1, and the dimension in the second horizontal direction HD2 of the first opening OP1 has a size of L2 that is larger than L1. The dimension in the second horizontal direction HD2 of the first opening OP1 may be larger than the dimension in the second horizontal direction HD2 of the first semiconductor chip 21 and the dimension in the second horizontal direction HD2 of the second semiconductor chip 22.

The second opening OP2 exposes a region including the second boundary B2 of the first chip overlapping region COR1. The second opening OP2 may expose an edge section of the first chip overlapping region COR1 including the second boundary B2 of the first chip overlapping region COR1, and the peripheral region PR that abuts the edge section. The second opening OP2 vertically overlaps an edge section of the first semiconductor chip 21 including the second side surface S2. As illustrated in FIG. 3, the second opening OP2 overlaps the first semiconductor chip 21 by a second width OL2 in the first horizontal direction HD1. The second width OL2 may have a size of 20 μm or more.

The second opening OP2 may be configured such that the dimension thereof in the second horizontal direction HD2 has a size larger than the dimension thereof in the first horizontal direction HD1. The dimension in the second horizontal direction HD2 of the second opening OP2 may be smaller than the dimension in the second horizontal direction HD2 of the first chip overlapping region COR1. As illustrated in FIG. 1, the dimension in the second horizontal direction HD2 of the first chip overlapping region COR1 has the size of L1, and the dimension in the second horizontal direction HD2 of the second opening OP2 has a size of L3 that is smaller than L1. The dimension in the second horizontal direction HD2 of the second opening OP2 may be smaller than the dimension in the second horizontal direction HD2 of the first semiconductor chip 21. The dimension in the second horizontal direction HD2 of the second opening OP2 may be smaller than the dimension in the second horizontal direction HD2 of the first opening OP1.

The third opening OP3 exposes a region including the sixth boundary B6 of the second chip overlapping region COR2. The third opening OP3 may expose an edge section of the second chip overlapping region COR2 including the sixth boundary B6 of the second chip overlapping region COR2, and the peripheral region PR that abuts the edge section. The third opening OP3 vertically overlaps an edge section of the second semiconductor chip 22. The third opening OP3 vertically overlaps the sixth side surface S6 of the second semiconductor chip 22. As illustrated in FIG. 3, the third opening OP3 overlaps the second semiconductor chip 22 by a sixth width OL6 in the first horizontal direction HD1. The sixth width OL6 may have a size of 20 μm or more.

The third opening OP3 may be configured such that the dimension thereof in the second horizontal direction HD2 has a size larger than the dimension thereof in the first horizontal direction HD1. The dimension in the second horizontal direction HD2 of the third opening OP3 may be smaller than the dimension in the second horizontal direction HD2 of the second chip overlapping region COR2. The dimension in the second horizontal direction HD2 of the third opening OP3 may be smaller than the dimension in the second horizontal direction HD2 of the second semiconductor chip 22. The dimension in the second horizontal direction HD2 of the third opening OP3 may be smaller than the dimension in the second horizontal direction HD2 of the first opening OP1. The dimension in the second horizontal direction HD2 of the third opening OP3 may have the same size as the dimension in the second horizontal direction HD2 of the second opening OP2.

The fourth opening OP4 may expose a region including the third boundary B3 of the first chip overlapping region COR1. The fourth opening OP4 may expose an edge section of the first chip overlapping region COR1 including the third boundary B3 of the first chip overlapping region COR1, and the peripheral region PR that abuts the edge section. The fourth opening OP4 vertically overlaps an edge section of the first semiconductor chip 21. The fourth opening OP4 vertically overlaps the third side surface S3 of the first semiconductor chip 21. As illustrated in FIG. 4 and FIG. 5, the fourth opening OP4 overlaps the first semiconductor chip 21 by a third width OL3 in the second horizontal direction HD2. The third width OL3 may have a size of 20 μm or more.

The fourth opening OP4 may be configured such that the dimension thereof in the first horizontal direction HD1 has a size larger than the dimension thereof in the second horizontal direction HD2. The dimension in the first horizontal direction HD1 of the fourth opening OP4 may be smaller than the dimension in the first horizontal direction HD1 of the first chip overlapping region COR1. The dimension in the first horizontal direction HD1 of the fourth opening OP4 may be smaller than the dimension in the first horizontal direction HD1 of the first semiconductor chip 21. The fourth opening OP4 may be connected to the first opening OP1. The fourth opening OP4 may intersect with the first opening OP1. The fourth opening OP4 may be configured integrally with the first opening OP1.

The fifth opening OP5 exposes a region including the fourth boundary B4 of the first chip overlapping region COR1. The fifth opening OP5 may expose an edge section of the first chip overlapping region COR1 including the fourth boundary B4 of the first chip overlapping region COR1, and the peripheral region PR that abuts the edge section. The fifth opening OP5 vertically overlaps an edge section of the first semiconductor chip 21. The fifth opening OP5 vertically overlaps the fourth side surface S4 of the first semiconductor chip 21. As illustrated in FIG. 4 and FIG. 5, the fifth opening OP5 overlaps the first semiconductor chip 21 by a fourth width OL4 in the second horizontal direction HD2. The fourth width OL4 may have a size of 20 μm or more.

The fifth opening OP5 may be configured such that the dimension thereof in the first horizontal direction HD1 has a size larger than the dimension thereof in the second horizontal direction HD2. The dimension in the first horizontal direction HD1 of the fifth opening OP5 may be smaller than the dimension in the first horizontal direction HD1 of the first chip overlapping region COR1. The dimension in the first horizontal direction HD1 of the fifth opening OP5 may be smaller than the dimension in the first horizontal direction HD1 of the first semiconductor chip 21. The fifth opening OP5 may be connected to the first opening OP1. The fifth opening OP5 may intersect with the first opening OP1. The fifth opening OP5 may be configured integrally with the first opening OP1.

The sixth opening OP6 may expose a region including the seventh boundary B7 of the second chip overlapping region COR2. The sixth opening OP6 may expose an edge section of the second chip overlapping region COR2 including the seventh boundary B7 of the second chip overlapping region COR2, and the peripheral region PR that abuts the edge section. The sixth opening OP6 vertically overlaps the second semiconductor chip 22. The sixth opening OP6 vertically overlaps the seventh side surface S7 of the second semiconductor chip 22. As illustrated in FIG. 6 and FIG. 7, the sixth opening OP6 overlaps the second semiconductor chip 22 by a seventh width OL7 in the second horizontal direction HD2. The seventh width OL7 may have a size of 20 μm or more.

The sixth opening OP6 may be configured such that the dimension thereof in the first horizontal direction HD1 has a size larger than the dimension thereof in the second horizontal direction HD2. The dimension in the first horizontal direction HD1 of the sixth opening OP6 may be smaller than the dimension in the first horizontal direction HD1 of the second chip overlapping region COR2. The dimension in the first horizontal direction HD1 of the sixth opening OP6 may be smaller than the dimension in the first horizontal direction HD1 of the second semiconductor chip 22. The sixth opening OP6 may be connected to the first opening OP1. The sixth opening OP6 may intersect with the first opening OP1. The sixth opening OP6 may be configured integrally with the first opening OP1.

The seventh opening OP7 exposes a region including the eighth boundary B8 of the second chip overlapping region COR2. The seventh opening OP7 may expose an edge section of the second chip overlap region COR2 including the eighth boundary B8 of the second chip overlap region COR2, and the peripheral region PR that abuts the edge section. The seventh opening OP7 vertically overlaps the second semiconductor chip 22. The seventh opening OP7 vertically overlaps the eighth side surface S8 of the second semiconductor chip 22. As illustrated in FIG. 6 and FIG. 7, the seventh opening OP7 overlaps the second semiconductor chip 22 by an eighth width OL8 in the second horizontal direction HD2. The eighth width OL8 may have a size of 20 μm or more.

The seventh opening OP7 may be configured such that the dimension thereof in the first horizontal direction HD1 has a size larger than the dimension thereof in the second horizontal direction HD2. The dimension in the first horizontal direction HD1 of the seventh opening OP7 may be smaller than the dimension in the first horizontal direction HD1 of the second chip overlapping region COR2. The dimension in the first horizontal direction HD1 of the seventh opening OP7 may be smaller than the dimension in the first horizontal direction HD1 of the second semiconductor chip 22. The seventh opening OP7 may be connected to the first opening OP1. The seventh opening OP7 may intersect with the first opening OP1. The seventh opening OP7 may be configured integrally with the first opening OP1.

The eighth opening OP8 may expose the first bump bonding pads 12A. The eighth opening OP8 may be configured to expose the plurality of first bump bonding pads 12A all at once. As illustrated in FIG. 1, the eighth opening OP8 may be an H shape to expose, all at once, the first bump bonding pads 12A disposed in two columns in the second horizontal direction HD2. In correspondence to the arrangement structure of the first bump bonding pads 12A disposed in two columns in the second horizontal direction HD2, the eighth opening OP8 of the H shape may be configured in the first insulating layer 15. The eighth opening OP8 may be connected to a first through hole TH1 to be described later. The eighth opening OP8 intersects with the first through hole TH1. The first bumps BM1 may be bonded to the first bump bonding pads 12A exposed by the eighth opening OP8. The first semiconductor chip 21 may be electrically connected to the first bump bonding pads 12A through the first bumps BM1. The eighth opening OP8 may be connected to the fourth opening OP4 and the fifth opening OP5. The eighth opening OP8 may intersect with the fourth opening OP4 and the fifth opening OP5. The eighth opening OP8 may be configured integrally with the fourth opening OP4 and the fifth opening OP5.

The ninth opening OP9 may expose the second bump bonding pads 12B. The ninth opening OP9 may be configured to expose the plurality of second bump bonding pads 12B all at once. As illustrated in FIG. 1, the ninth opening OP9 may be an H shape to expose, all at once, the second bump bonding pads 12B disposed in two columns in the second horizontal direction HD2. The ninth opening OP9 may be connected to a second through hole TH2 to be described later. The ninth opening OP9 intersects with the second through hole TH2. In correspondence to the arrangement structure of the second bump bonding pads 12B disposed in two columns in the second horizontal direction HD2, the ninth opening OP9 of the H shape may be configured in the first insulating layer 15. The second bumps BM2 may be bonded to the second bump bonding pads 12B exposed by the ninth opening OP9. The second semiconductor chip 22 may be electrically connected to the second bump bonding pads 12B through the second bumps BM2. The ninth opening OP9 may be connected to the sixth opening OP6 and the seventh opening OP7. The ninth opening OP9 may intersect with the sixth opening OP6 and the seventh opening OP7. The ninth opening OP9 may be configured integrally with the sixth opening OP6 and the seventh opening OP7.

The first metal patterns 13 are disposed on the top surface 11T of the body layer 11. The first metal patterns 13 may include signal wirings, ground patterns and power patterns. The first metal patterns 13 may be covered with the first insulating layer 15. The first metal patterns 13 might not be exposed through the first to seventh openings OP1 to OP7.

The second metal patterns 14 may be disposed on a bottom surface 11B of the body layer 11. Some of the second metal patterns 14 may include ball lands 14A. The second insulating layer 16 is disposed on the bottom surface 11B of the body layer 11, and may have openings that expose the ball lands 14A. The external connection terminals 40 may be attached to the ball lands 14A. The external connection terminals 40 may include solder balls.

The first through hole TH1 and the second through hole TH2 that pass through the package substrate 10A including the body layer 11 and the second insulating layer 16 are configured. The first through hole TH1 vertically passes through the package substrate 10A in the first chip overlapping region COR1, and the second through hole TH2 vertically passes through the package substrate 10A in the second chip overlapping region COR2. The first through hole TH1 is exposed through the eighth opening OP8. The first through hole TH1 is connected to the eighth opening OP8. The first through hole TH1 intersects with the eighth opening OP8. The second through hole TH2 is exposed through the ninth opening OP9. The second through hole TH2 is connected to the ninth opening OP9. The second through hole TH2 intersects with the ninth opening OP9.

In an embodiment, in a molding process of forming the molding layer 30, the molding layer 30 may be formed as air is discharged through the first and second through holes TH1 and TH2. In an embodiment, the first and second through holes TH1 and TH2 may be vent holes for the discharge of air.

The molding layer 30 may include a top molding section 31, first and second extending sections 32A and 32B and a bottom molding section 33. The molding layer 30 may be formed by a molding process using a liquid molding material. The molding material may include an epoxy molding compound (EMC). The epoxy molding compound (EMC) may include resin and filler.

The top molding section 31 fills the space between the first semiconductor chip 21 and the package substrate 10A and the space between the second semiconductor chip 22 and the package substrate 10A, and surrounds the first and second semiconductor chips 21 and 22 and the first and second bumps BM1 and BM2. During the molding process, vacuum evacuation may occur through the first and second through holes TH1 and TH2 of the package substrate 10A. By the difference between a pressure with which the molding material is injected and the pressure due to vacuum evacuation through the first and second through holes TH1, TH2, the molding material may flow into the space between the first semiconductor chip 21 and the package substrate 10A and the space between the second semiconductor chip 22 and the package substrate 10A. Thus, the space between the first semiconductor chip 21 and the package substrate 10A and the space between the second semiconductor chip 22 and the package substrate 10A may be filled with the top molding section 31.

In an embodiment, the top molding section 31 may surround the first and second semiconductor chips 21 and 22 and the first and second bumps BM1 and BM2 to protect them from an external environment. In the present embodiment, the top molding section 31 covers the top surfaces of the first and second semiconductor chips 21 and 22. In an embodiment, the top molding section 31 may expose the top surfaces of the first and second semiconductor chips 21 and 22.

In an embodiment, passages through which the molding material is introduced are widened by the first to seventh openings OP1 to OP7. Thus, the flowability of the molding material that flows into the space between the first semiconductor chip 21 and the package substrate 10A and the space between the second semiconductor chip 22 and the package substrate 10A may be improved. The first to ninth openings OP1 to OP9 are filled with the molding material. The top molding section 31 may extend to the first to ninth openings OP1 to OP9.

The molding material is introduced into the first and second through holes TH1 and TH2 during the molding process, and accordingly, the first extending section 32A that fills the first through hole TH1, the second extending section 32B that fills the second through hole TH2 and the bottom molding section 33 that protrudes on the bottom of the second insulating layer 16 may be formed. The bottom molding section 33 may have a bar shape or line shape that extends in the first horizontal direction HD1. The bottom molding section 33 may be disposed on the bottom surface of the package substrate 10A.

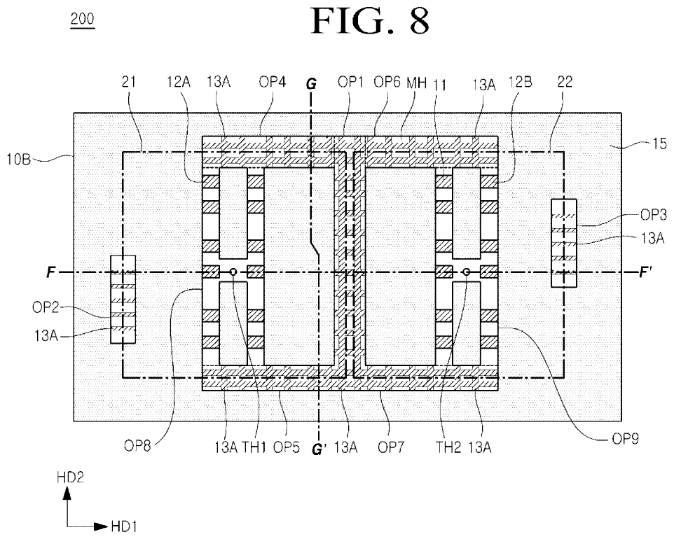

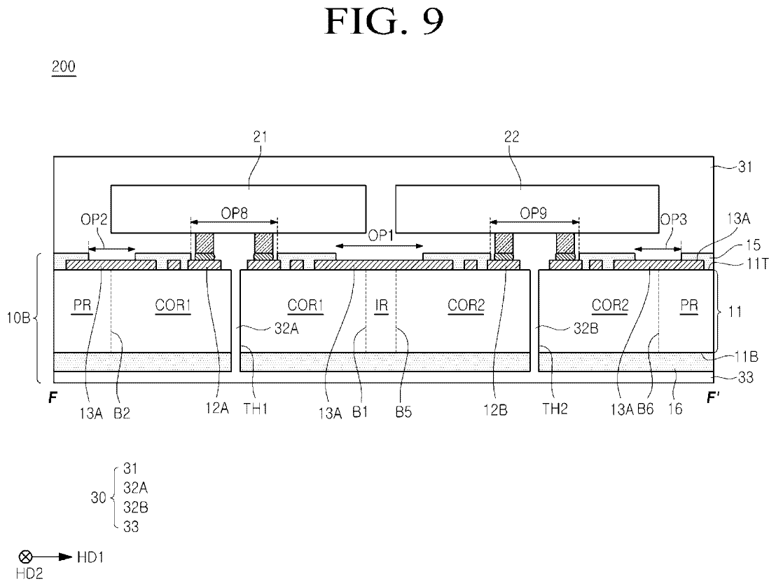

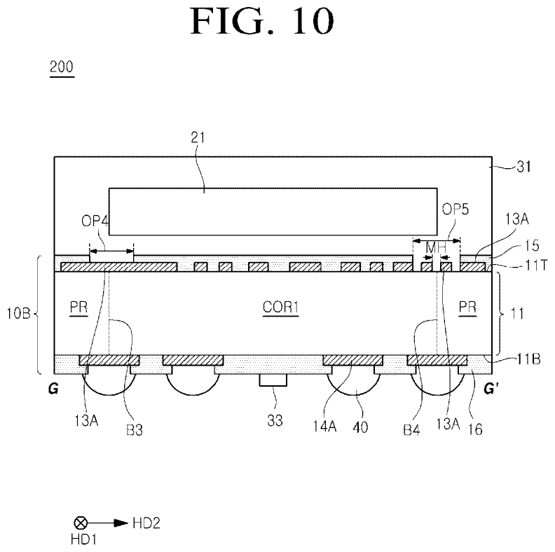

FIG. 8 is a plan view of a semiconductor package according to an embodiment of the present disclosure, FIG. 9 is a cross-sectional view taken along a line F-F′ of FIG. 8, and FIG. 10 is a cross-sectional view taken along a line G-G′ of FIG. 8.

Referring to FIG. 8 to FIG. 10, some of first metal patterns 13A of a package substrate 10B of a semiconductor package 200 may be exposed through first to seventh openings OP1 to OP7. Some of the first metal patterns 13A may be exposed through the first to seventh openings OP1 to OP7, and the other some may be covered with a first insulating layer 15. The first metal patterns 13A may have a plate shape. The first metal patterns 13A exposed through the first to seventh openings OP1 to OP7 may have a mesh shape that includes a plurality of holes MH. The first metal patterns 13A may be continuous in regions where the first to seventh openings OP1 to OP7 are disposed. Therefore, the first metal patterns 13A may electrically connect both sides of the regions where the first to seventh openings OP1 to OP7 are disposed. The first metal patterns 13A that are exposed through the first opening OP1 may electrically connect a first chip overlapping region COR1 and a second chip overlapping region COR2. The first metal patterns 13A that are exposed through the second opening OP2 may electrically connect a peripheral region PR and the first chip overlapping region COR1. The first metal patterns 13A that are exposed through the third opening OP3 may electrically connect the peripheral region PR and the second chip overlapping region COR2. The first metal patterns 13A that are exposed through the fourth opening OP4 may electrically connect the peripheral region PR and the first chip overlapping region COR1. The first metal patterns 13A that are exposed through the fifth opening OP5 may electrically connect the peripheral region PR and the first chip overlapping region COR1. The first metal patterns 13A that are exposed through the sixth opening OP6 may electrically connect the peripheral region PR and the second chip overlapping region COR2. The first metal patterns 13A that are exposed through the seventh opening OP7 may electrically connect the peripheral region PR and the second chip overlapping region COR2. A molding layer 30 may be filled in the holes MH of the first metal patterns 13A having the mesh shape in the first to seventh openings OP1 to OP7. In an embodiment, the first metal patterns 13A may be ground patterns. In another embodiment, the first metal patterns 13A may be power patterns.

During semiconductor operation, IR drop can occur due to resistance in the power delivery path. Excessive IR drop leads to instability in the supply and ground voltages, which in turn can cause signal distortion and degrade signal integrity. To prevent such issues, a stable power delivery network is essential. In semiconductor packaging, achieving stable power delivery requires distributing power and ground patterns evenly across the entire package substrate. This ensures consistent voltage levels throughout the circuit and helps maintain both power integrity and signal integrity. According to an embodiment of the present disclosure, because power patterns or ground patterns are continuous—without interruption—in the regions where the first to seventh openings OP1 to OP7 are disposed, a stable power supply can be maintained around the openings. For example, either of first and second semiconductor chips 21 and 22 disposed on both sides of the first opening OP1 may require a significantly increased power supply for a limited duration during transient operation states such as initialization or mode switching. Because either the first or second semiconductor chips 21 and 22 is connected through the power patterns and/or ground patterns exposed through the first opening OP1 to power patterns and/or ground patterns connected to the other of the first and second semiconductor chips 21 and 22, a stable power supply may be achieved. Thus, an IR drop may be minimized or suppressed.

During the transportation and storage of package substrates 10B, and manufacturing process of semiconductor package, the package substrates 10B may come into contact with each other or with other external materials. The first metal patterns 13A exposed through the first to seventh openings OP1 to OP7 may be directly affected by such contact. The first metal patterns 13A exposed through the first to seventh openings OP1 to OP7 may be damaged, resulting in scratches and open circuits. The first metal patterns 13A exposed through the first to seventh openings OP1 to OP7 may be connected in parallel along at least two lines in which the same power and/or ground potential constitutes a mesh pattern. Accordingly, even when some of metal patterns exposed through openings are damaged or cut, the effect on the operation of the semiconductor package 200 may be minimized.

Although the first metal patterns 13A are exposed through all of the first to seventh openings OP1 to OP7, the present disclosure is not limited thereto. The first metal patterns 13A may be exposed through at least one of the first to seventh openings OP1 to OP7.

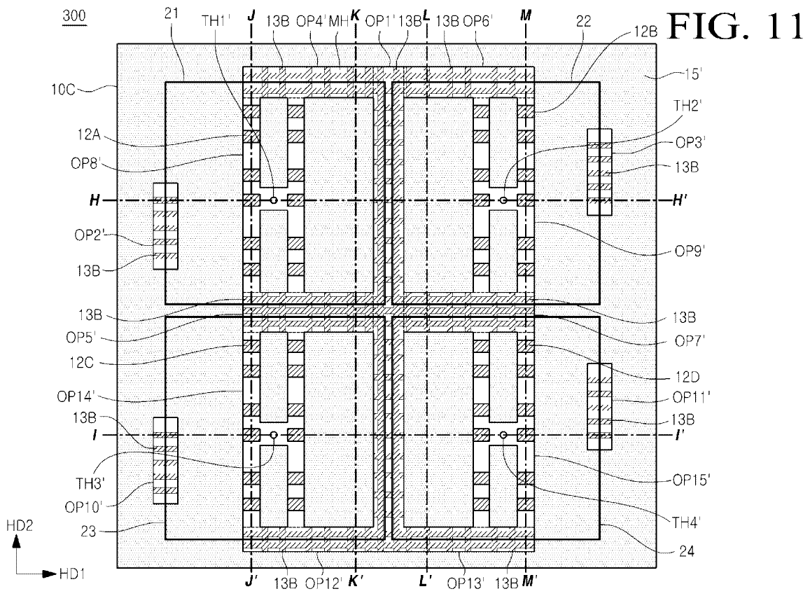

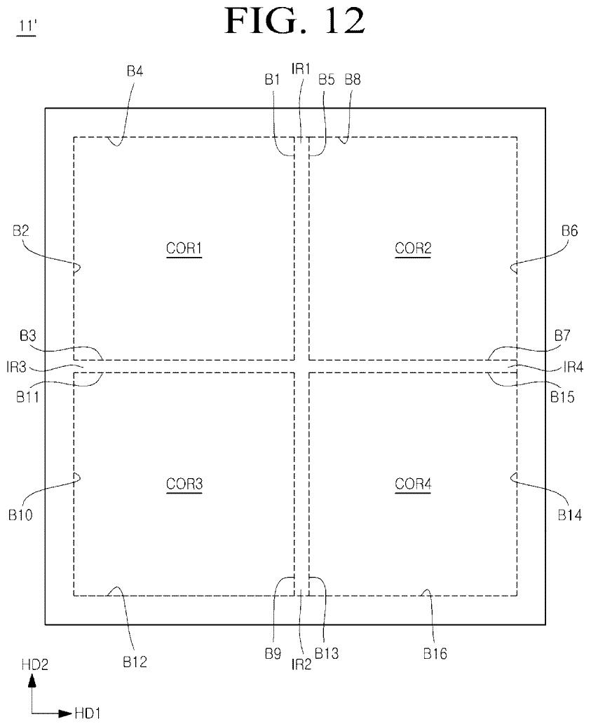

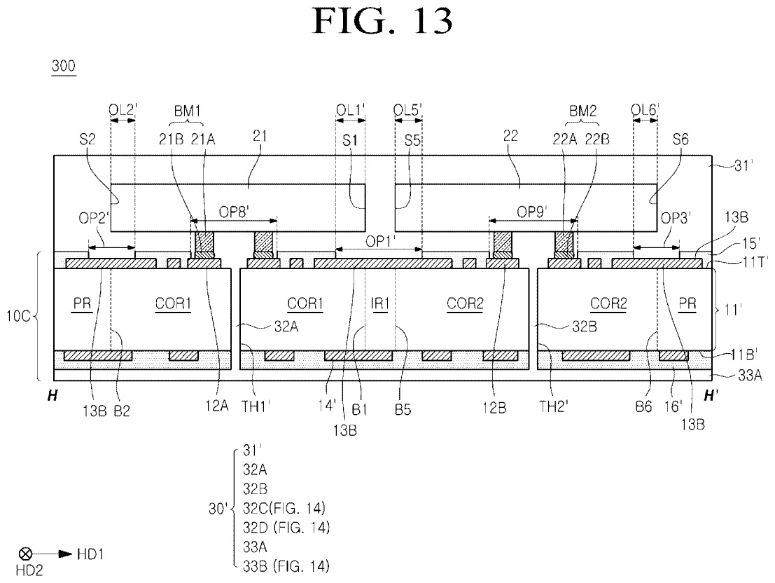

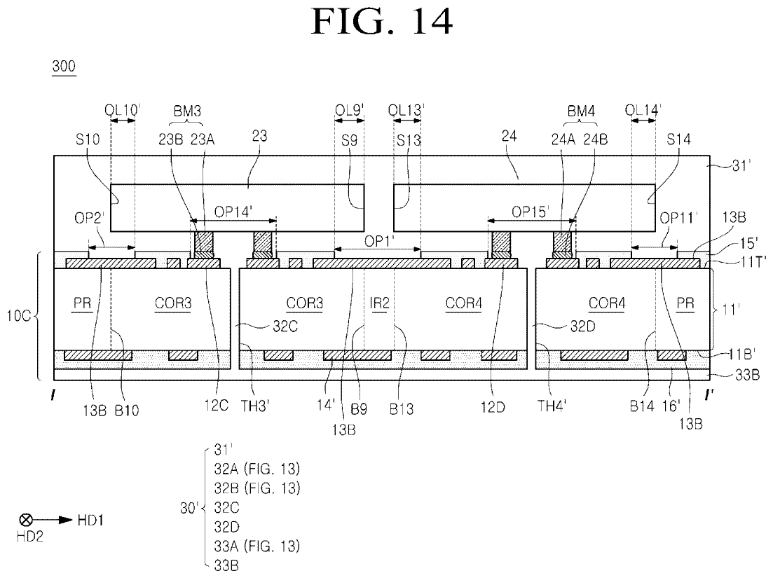

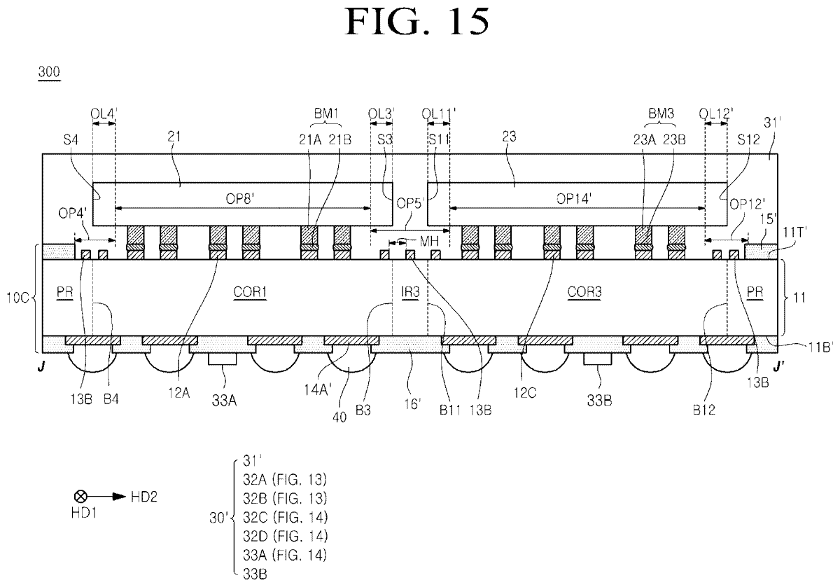

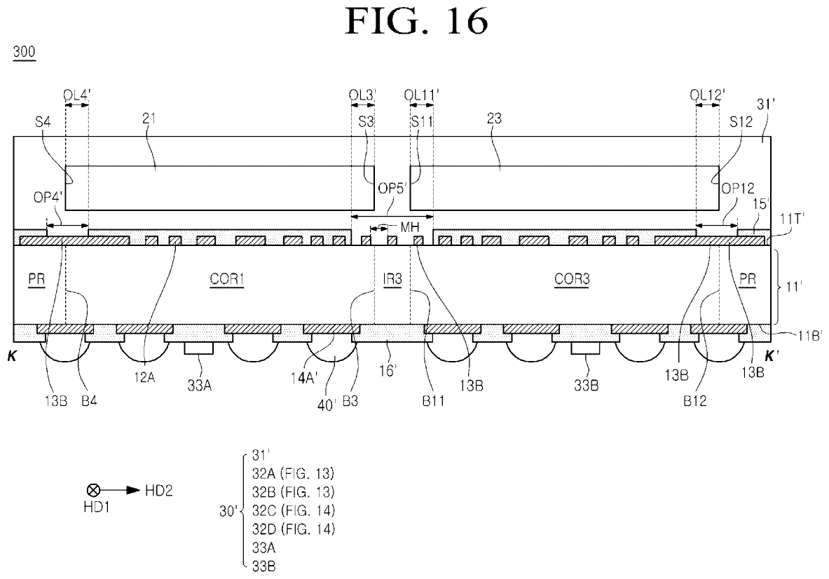

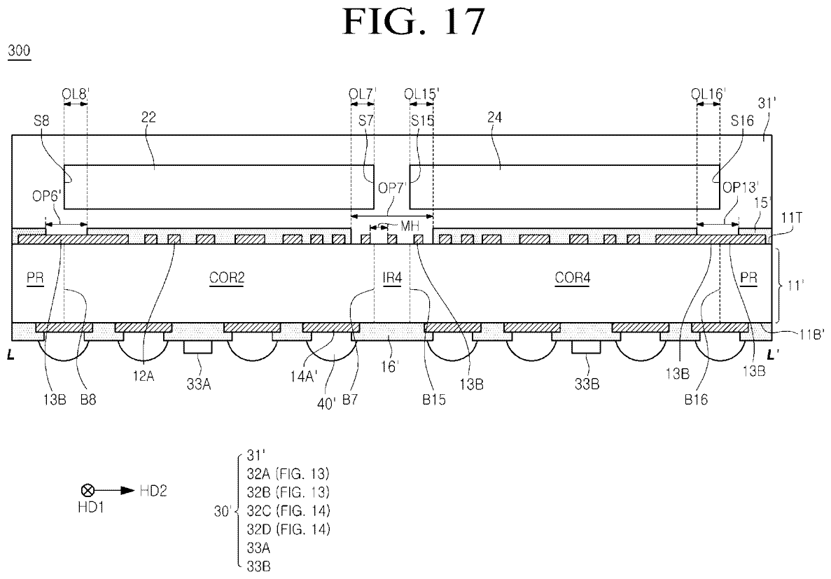

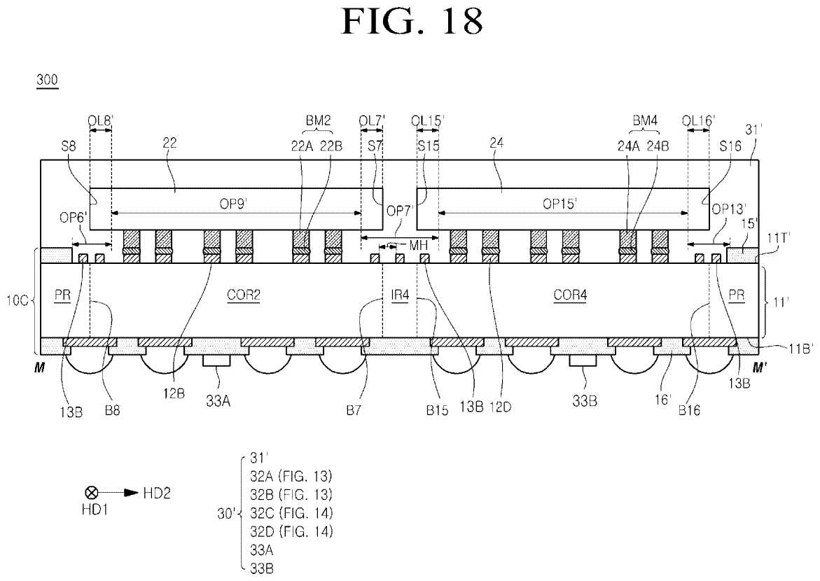

FIG. 11 is a plan view of a semiconductor package according to an embodiment of the present disclosure, FIG. 12 is a plan view schematically illustrating the body layer of a package substrate of FIG. 11, FIG. 13 is a cross-sectional view taken along a line H-H′ of FIG. 11, FIG. 14 is a cross-sectional view taken along a line I-I′ of FIG. 11, FIG. 15 is a cross-sectional view taken along a line J-J′ of FIG. 11, FIG. 16 is a cross-sectional view taken along a line K-K′ of FIG. 11, FIG. 17 is a cross-sectional view taken along a line L-L′ of FIG. 11, and FIG. 18 is a cross-sectional view taken along a line M-M′ of FIG. 11.

Referring to FIG. 11 to FIG. 18, a semiconductor package 300 according to an embodiment of the present disclosure includes a package substrate 10C, first, second, third and fourth semiconductor chips 21, 22, 23 and 24, a molding layer 30′and external connection terminals 40′. In order to facilitate understanding, illustration of the molding layer 30′ is omitted in FIG. 11.

The first, second, third and fourth semiconductor chips 21, 22, 23 and 24 are mounted on the package substrate 10C. The first semiconductor chip 21 is bonded onto the package substrate 10C by the medium of first bumps BM1. The first bump BM1 includes a first metal layer 21A and a first solder layer 21B. The second semiconductor chip 22 is bonded onto the package substrate 10C by the medium of second bumps BM2. The second bump BM2 includes a second metal layer 22A and a second solder layer 22B. The third semiconductor chip 23 is bonded onto the package substrate 10C by the medium of third bumps BM3. The third bump BM3 includes a third metal layer 23A and a third solder layer 23B. The fourth semiconductor chip 24 is bonded onto the package substrate 10C by the medium of fourth bumps BM4. The fourth bump BM4 includes a fourth metal layer 24A and a fourth solder layer 24B.

The first, second, third and fourth semiconductor chips 21, 22, 23 and 24 are disposed in the form of a 2×2 matrix in a first horizontal direction HD1 and a second horizontal direction HD2. The first semiconductor chip 21 is disposed next to the second semiconductor chip 22 in the first horizontal direction HD1, the third semiconductor chip 23 is disposed next to the fourth semiconductor chip 24 in the first horizontal direction HD1, the first semiconductor chip 21 is disposed next to the third semiconductor chip 23 in the second horizontal direction HD2, and the second semiconductor chip 22 is disposed next to the fourth semiconductor chip 24 in the second horizontal direction HD2. The first, second, third and fourth semiconductor chips 21, 22, 23 and 24 are disposed to be spaced apart from each other.

The package substrate 10C includes a body layer 11′, first bump bonding pads 12A, second bump bonding pads 12B, third bump bonding pads 12C, fourth bump bonding pads 12D, first metal patterns 13B, second metal patterns 14′, a first insulating layer 15′, and a second insulating layer 16′.

The body layer 11′ includes a first chip overlapping region COR1 that vertically overlaps the first semiconductor chip 21, a second chip overlapping region COR2 that vertically overlaps the second semiconductor chip 22, a third chip overlapping region COR3 that vertically overlaps the third semiconductor chip 23, and a fourth chip overlapping region COR4 that vertically overlaps the fourth semiconductor chip 24. The body layer 11′ includes a first intermediate region IR1 between the first chip overlapping region COR1 and the second chip overlapping region COR2, a second intermediate region IR2 between the third chip overlapping region COR3 and the fourth chip overlapping region COR4, a third intermediate region IR3 between the first chip overlapping region COR1 and the third chip overlapping region COR3, and a fourth intermediate region IR4 between the second chip overlapping region COR2 and the fourth chip overlapping region COR4. The body layer 11′ includes the first, second, third and fourth chip overlapping regions COR1, COR2, COR3 and COR4 and a peripheral region PR. The peripheral region PR is a region that surrounds the first, second, third and fourth chip overlapping regions COR1, COR2, COR3 and COR4 and the first, second, third and fourth intermediate regions IR1, IR2, IR3 and IR4.

The first semiconductor chip 21 includes a first side surface S1 and a second side surface S2 that face each other in the first horizontal direction HD1, and a third side surface S3 and a fourth side surface S4 that face each other in the second horizontal direction HD2. First, second, third and fourth boundaries B1, B2, B3 and B4 of the first chip overlapping region COR1 of the body layer 11′ correspond to the first, second, third and fourth side surfaces S1, S2, S3 and S4, respectively, of the first semiconductor chip 21. The first boundary B1 of the first chip overlapping region COR1 abuts the first intermediate region IR1, the third boundary B3 of the first chip overlapping region COR1 abuts the third intermediate region IR3, and the second and fourth boundaries B2 and B4 of the first chip overlapping region COR1 abut the peripheral region PR.

The second semiconductor chip 22 includes a fifth side surface S5 and a sixth side surface S6 that face each other in the first horizontal direction HD1, and a seventh side surface S7 and an eighth side surface S8 that face each other in the second horizontal direction HD2. Fifth, sixth, seventh and eighth boundaries B5, B6, B7 and B8 of the second chip overlapping region COR2 of the body layer 11′ correspond to the fifth, sixth, seventh and eighth side surfaces S5, S6, S7 and S8, respectively, of the second semiconductor chip 22. The fifth boundary B5 of the second chip overlapping region COR2 abuts the first intermediate region IR1, the seventh boundary B7 of the second chip overlapping region COR2 abuts the fourth intermediate region IR4, and the sixth and eight boundaries B6 and B8 of the second chip overlapping region COR2 abut the peripheral region PR.

The third semiconductor chip 23 includes a ninth side surface S9 and a tenth side surface S10 that face each other in the first horizontal direction HD1, and an eleventh side surface S11 and a twelfth side surface S12 that face each other in the second horizontal direction HD2. Ninth, tenth, eleventh and twelfth boundaries B9, B10, B11 and B12 of the third chip overlapping region COR3 of the body layer 11′ correspond to the ninth, tenth, eleventh and twelfth side surfaces S9, S10, S11 and S12, respectively, of the third semiconductor chip 23. The ninth boundary B9 of the third chip overlapping region COR3 abuts the second intermediate region IR2, the eleventh boundary B11 of the third chip overlapping region COR3 abuts the third intermediate region IR3, and the tenth and twelfth boundaries B10 and B12 of the third chip overlapping region COR3 abut the peripheral region PR.

The fourth semiconductor chip 24 includes a thirteenth side surface S13 and a fourteenth side surface S14 that face each other in the first horizontal direction HD1, and a fifteenth side surface S15 and a sixteenth side surface S16 that face each other in the second horizontal direction HD2. Thirteenth, fourteenth, fifteenth and sixteenth boundaries B13, B14, B15 and B16 of the fourth chip overlapping region COR4 of the body layer 11′ correspond to the thirteenth, fourteenth, fifteenth and sixteenth side surfaces S13, S14, S15 and S16, respectively, of the fourth semiconductor chip 24. The thirteenth boundary B13 of the fourth chip overlapping region COR4 abuts the second intermediate region IR2, the fifteenth boundary B15 of the fourth chip overlapping region COR4 abuts the fourth intermediate region IR4, and the fourteenth and sixteenth boundaries B14 and B16 of the fourth chip overlapping region COR4 abut the peripheral region PR.

The first, second, third and fourth bump bonding pads 12A, 12B, 12C and 12D are disposed on a top surface 11T′ of the body layer 11′. The first bump bonding pads 12A are disposed on the first chip overlapping region COR1, the second bump bonding pads 12B are disposed on the second chip overlapping region COR2, the third bump bonding pads 12C are disposed on the third chip overlapping region COR3, and the fourth bump bonding pads 12D are disposed on the fourth chip overlapping region COR4.

The first insulating layer 15′ is disposed on the top surface 11T′ of the body layer 11′. The first insulating layer 15′ may include a photosensitive solder resist.

The first insulating layer 15′ includes first to fifteenth openings OP1′ to OP15′.

The first opening OP1′ may expose the first and second intermediate regions IR1 and IR2, an edge section of the first chip overlapping region COR1 including the first boundary B1, an edge section of the second chip overlapping region COR2 including the fifth boundary B5, an edge section of the third chip overlapping region COR3 including the ninth boundary B9, and an edge section of the fourth chip overlapping region COR4 including the thirteenth boundary B13.

The first opening OP1′ vertically overlaps the first semiconductor chip 21. The first opening OP1′ vertically overlaps the first side surface S1 of the first semiconductor chip 21. As illustrated in FIG. 13, the first opening OP1′ overlaps the first semiconductor chip 21 by a first width OL1′ in the first horizontal direction HD1. The first opening OP1′ vertically overlaps the second semiconductor chip 22. The first opening OP1′ vertically overlaps the fifth side surface S5 of the second semiconductor chip 22. As illustrated in FIG. 13, the first opening OP1′ overlaps the second semiconductor chip 22 by a fifth width OL5′ in the first horizontal direction HD1. The first opening OP1′ vertically overlaps the third semiconductor chip 23. The first opening OP1′ vertically overlaps the ninth side surface S9 of the third semiconductor chip 23. As illustrated in FIG. 14, the first opening OP1′ overlaps the third semiconductor chip 23 by a ninth width OL9′ in the first horizontal direction HD1. The first opening OP1′ vertically overlaps the fourth semiconductor chip 24. The first opening OP1′ vertically overlaps the thirteenth side surface S13 of the fourth semiconductor chip 24. As illustrated in FIG. 14, the first opening OP1′ overlaps the fourth semiconductor chip 24 by a thirteenth width OL13′ in the first horizontal direction HD1. Each of the first width OL1′, the fifth width OL5′, the ninth width OL9′ and the thirteenth width OL13′ may have a size of 20 μm or more.

The dimension in the first horizontal direction HD1 of the first opening OP1′ is larger than the dimension in the first horizontal direction HD1 of the first intermediate region IR1 and the dimension in the first horizontal direction HD1 of the second intermediate region IR2. The dimension in the second horizontal direction HD2 of the first opening OP1′ may be larger than the sum of the dimension in the second horizontal direction HD2 of the first chip overlapping region COR1 and the dimension in the second horizontal direction HD2 of the second chip overlapping region COR2. The dimension in the second horizontal direction HD2 of the first opening OP1′ may be larger than the sum of the dimension in the second horizontal direction HD2 of the first semiconductor chip 21 and the dimension in the second horizontal direction HD2 of the second semiconductor chip 22.

The second opening OP2′ exposes a region including the second boundary B2 of the first chip overlapping region COR1. The second opening OP2′ may expose an edge section of the first chip overlapping region COR1 including the second boundary B2 of the first chip overlapping region COR1, and the peripheral region PR that abuts the edge section. The second opening OP2′ vertically overlaps the first semiconductor chip 21. The second opening OP2′ vertically overlaps the second side surface S2 of the first semiconductor chip 21. As illustrated in FIG. 13, the second opening OP2′ overlaps the first semiconductor chip 21 by a second width OL2′ in the first horizontal direction HD1. The second width OL2′ may have a size of 20 μm or more.

The second opening OP2′ may be configured such that the dimension thereof in the second horizontal direction HD2 has a size larger than the dimension thereof in the first horizontal direction HD1. The dimension in the second horizontal direction HD2 of the second opening OP2′ may be smaller than the dimension in the second horizontal direction HD2 of the first chip overlapping region COR1. The dimension in the second horizontal direction HD2 of the second opening OP2′ may be smaller than the dimension in the second horizontal direction HD2 of the first semiconductor chip 21. The dimension in the second horizontal direction HD2 of the second opening OP2′ may be smaller than the dimension in the second horizontal direction HD2 of the first opening OP1′.

The third opening OP3′ exposes a region including the sixth boundary B6 of the second chip overlapping region COR2. The third opening OP3′ may expose an edge section of the second chip overlapping region COR2 including the sixth boundary B6 of the second chip overlapping region COR2, and the peripheral region PR that abuts the edge section. The third opening OP3′ vertically overlaps the second semiconductor chip 22. The third opening OP3′ vertically overlaps the sixth side surface S6 of the second semiconductor chip 22. As illustrated in FIG. 13, the third opening OP3′ overlaps the second semiconductor chip 22 by a sixth width OL6′ in the first horizontal direction HD1. The sixth width OL6′ may have a size of 20 μm or more.

The third opening OP3′ may be configured such that the dimension thereof in the second horizontal direction HD2 has a size larger than the dimension thereof in the first horizontal direction HD1. The dimension in the second horizontal direction HD2 of the third opening OP3′ may be smaller than the dimension in the second horizontal direction HD2 of the second chip overlapping region COR2. The dimension in the second horizontal direction HD2 of the third opening OP3′ may be smaller than the dimension in the second horizontal direction HD2 of the second semiconductor chip 22. The dimension in the second horizontal direction HD2 of the third opening OP3′ may be smaller than the dimension in the second horizontal direction HD2 of the first opening OP1′. The dimension in the second horizontal direction HD2 of the third opening OP3′ may have the same size as the dimension in the second horizontal direction HD2 of the second opening OP2′.

The fourth opening OP4′ may expose a region including the fourth boundary B4 of the first chip overlapping region COR1. The fourth opening OP4′ may expose an edge section of the first chip overlapping region COR1 including the fourth boundary B4 of the first chip overlapping region COR1, and the peripheral region PR that abuts the edge section. The fourth opening OP4′ vertically overlaps an edge section of the first semiconductor chip 21 including the fourth side surface S4. As illustrated in FIG. 15 and FIG. 16, the fourth opening OP4′ overlaps the first semiconductor chip 21 by a fourth width OL4′ in the second horizontal direction HD2. The fourth width OL4′ may have a size of 20 μm or more.

The fourth opening OP4′ may be configured such that the dimension thereof in the first horizontal direction HD1 has a size larger than the dimension thereof in the second horizontal direction HD2. The dimension in the first horizontal direction HD1 of the fourth opening OP4′ may be smaller than the dimension in the first horizontal direction HD1 of the first chip overlapping region COR1. The dimension in the first horizontal direction HD1 of the fourth opening OP4′ may be smaller than the dimension in the first horizontal direction HD1 of the first semiconductor chip 21. The fourth opening OP4′ may be connected to the first opening OP1′. The fourth opening OP4′ may intersect with the first opening OP1′. The fourth opening OP4′ may be configured integrally with the first opening OP1′.

The fifth opening OP5′ may expose the third intermediate region IR3, an edge section of the first chip overlapping region COR1 including the third boundary B3, and an edge section of the third chip overlapping region COR3 including the eleventh boundary B11. The fifth opening OP5′ vertically overlaps an edge section of the first semiconductor chip 21 including the third side surface S3. As illustrated in FIG. 15 and FIG. 16, the fifth opening OP5′ overlaps the first semiconductor chip 21 by a third width OL3′ in the second horizontal direction HD2. The fifth opening OP5′ vertically overlaps an edge section of the third semiconductor chip 23 including the eleventh side surface S11. As illustrated in FIG. 15 and FIG. 16, the fifth opening OP5′ overlaps the third semiconductor chip 23 by an eleventh width OL11′ in the second horizontal direction HD2. Each of the third width OL3′ and the eleventh width OL11′ may have a size of 20 μm or more.

The fifth opening OP5′ may be configured such that the dimension thereof in the first horizontal direction HD1 has a size larger than the dimension thereof in the second horizontal direction HD2. The dimension in the first horizontal direction HD1 of the fifth opening OP5′ may be smaller than the dimension in the first horizontal direction HD1 of the first chip overlapping region COR1 and the dimension in the first horizontal direction HD1 of the third chip overlapping region COR3. The dimension in the first horizontal direction HD1 of the fifth opening OP5′ may be smaller than the dimension in the first horizontal direction HD1 of the first semiconductor chip 21 and the dimension in the first horizontal direction HD1 of the third semiconductor chip 23. The fifth opening OP5′ may be connected to the first opening OP1′. The fifth opening OP5′ may intersect with the first opening OP1′. The fifth opening OP5′ may be configured integrally with the first opening OP1′.

The sixth opening OP6′ may expose a region including the eighth boundary B8 of the second chip overlapping region COR2. The sixth opening OP6′ may expose an edge section of the second chip overlapping region COR2 including the eighth boundary B8 of the second chip overlapping region COR2, and the peripheral region PR that abuts the edge section. The sixth opening OP6′ vertically overlaps an edge section of the second semiconductor chip 22 including the eighth side surface S8. As illustrated in FIG. 17 and FIG. 18, the sixth opening OP6′ overlaps the second semiconductor chip 22 by an eighth width OL8′ in the second horizontal direction HD2. The eighth width OL8′ may have a size of 20 μm or more.

The sixth opening OP6′ may be configured such that the dimension thereof in the first horizontal direction HD1 has a size larger than the dimension thereof in the second horizontal direction HD2. The dimension in the first horizontal direction HD1 of the sixth opening OP6′ may be smaller than the dimension in the first horizontal direction HD1 of the second chip overlapping region COR2. The dimension in the first horizontal direction HD1 of the sixth opening OP6′ may be smaller than the dimension in the first horizontal direction HD1 of the second semiconductor chip 22. The sixth opening OP6′ may be connected to the first opening OP1′. The sixth opening OP6′ may intersect with the first opening OP1′. The sixth opening OP6′ may be configured integrally with the first opening OP1′.

The seventh opening OP7′ may expose the fourth intermediate region IR4, an edge section of the second chip overlapping region COR2 including the seventh boundary B7, and an edge section of the fourth chip overlapping region COR4 including the fifteenth boundary B15. The seventh opening OP7′ vertically overlaps an edge section of the second semiconductor chip 22 including the seventh side surface S7. As illustrated in FIG. 17 and FIG. 18, the seventh opening OP7′ overlaps the second semiconductor chip 22 by a seventh width OL7′ in the second horizontal direction HD2. The seventh opening OP7′ vertically overlaps an edge section of the fourth semiconductor chip 24 including the fifteenth side surface S15. As illustrated in FIG. 17 and FIG. 18, the seventh opening OP7′ overlaps the fourth semiconductor chip 24 by a fifteenth width OL15′ in the second horizontal direction HD2. Each of the seventh width OL7′ and the fifteenth width OL15′ may have a size of 20 μm or more.

The seventh opening OP7′ may be configured such that the dimension thereof in the first horizontal direction HD1 has a size larger than the dimension thereof in the second horizontal direction HD2. The dimension in the first horizontal direction HD1 of the seventh opening OP7′ may be smaller than the dimension in the first horizontal direction HD1 of the second chip overlapping region COR2 and the dimension in the first horizontal direction HD1 of the fourth chip overlapping region COR4. The dimension in the first horizontal direction HD1 of the seventh opening OP7′ may be smaller than the dimension in the first horizontal direction HD1 of the second semiconductor chip 22 and the dimension in the first horizontal direction HD1 of the fourth semiconductor chip 24. The seventh opening OP7′ may be connected to the first opening OP1′. The seventh opening OP7′ may intersect with the first opening OP1′. The seventh opening OP7′ may be configured integrally with the first opening OP1′.

The eighth opening OP8′ may expose the first bump bonding pads 12A. The eighth opening OP8′ may be configured to expose the plurality of first bump bonding pads 12A all at once. As illustrated in FIG. 11, the eighth opening OP8′ may be an H shape to expose, all at once, the first bump bonding pads 12A disposed in two columns in the second horizontal direction HD2. In correspondence to the arrangement structure of the first bump bonding pads 12A disposed in two columns in the second horizontal direction HD2, the eighth opening OP8′ of the H shape may be configured in the first insulating layer 15′. The eighth opening OP8′ is connected to a first through hole TH1′ to be described later. The eighth opening OP8′ intersects with the first through hole TH1′. The first bumps BM1 may be bonded to the first bump bonding pads 12A exposed by the eighth opening OP8′. The first semiconductor chip 21 may be electrically connected to the first bump bonding pads 12A through the first bumps BM1. The eighth opening OP8′ may be connected to the fourth opening OP4′ and the fifth opening OP5′. The eighth opening OP8′ may intersect with the fourth opening OP4′ and the fifth opening OP5′. The eighth opening OP8′ may be configured integrally with the fourth opening OP4′ and the fifth opening OP5′.

The ninth opening OP9′ may expose the second bump bonding pads 12B. The ninth opening OP9′ may be configured to expose the plurality of second bump bonding pads 12B all at once. As illustrated in FIG. 11, the ninth opening OP9′ may be an H shape to expose, all at once, the second bump bonding pads 12B disposed in two columns in the second horizontal direction HD2. In correspondence to the arrangement structure of the second bump bonding pads 12B disposed in two columns in the second horizontal direction HD2, the ninth opening OP9′ of the H shape may be configured in the first insulating layer 15′. The ninth opening OP9′ is connected to a second through hole TH2′ to be described later. The ninth opening OP9′ intersects with the second through hole TH2′. The second bumps BM2 may be bonded to the second bump bonding pads 12B exposed by the ninth opening OP9′. The second semiconductor chip 22 may be electrically connected to the second bump bonding pads 12B through the second bumps BM2. The ninth opening OP9′ may be connected to the sixth opening OP6′ and the seventh opening OP7′. The ninth opening OP9′ may intersect with the sixth opening OP6′ and the seventh opening OP7′. The ninth opening OP9′ may be configured integrally with the sixth opening OP6′ and the seventh opening OP7′.

The tenth opening OP10′ exposes a region including the tenth boundary B10 of the third chip overlapping region COR3. The tenth opening OP10′ may expose an edge section of the third chip overlapping region COR3 including the tenth boundary B10 of the third chip overlapping region COR3, and the peripheral region PR that abuts the edge section. The tenth opening OP10′ vertically overlaps the third semiconductor chip 23. The tenth opening OP10′ vertically overlaps the tenth side surface S10 of the third semiconductor chip 23. As illustrated in FIG. 14, the tenth opening OP10′ overlaps the third semiconductor chip 23 by a tenth width OL10′ in the first horizontal direction HD1. The tenth width OL10′ may have a size of 20 μm or more.

The tenth opening OP10′ may be configured such that the dimension thereof in the second horizontal direction HD2 has a size larger than the dimension thereof in the first horizontal direction HD1. The dimension in the second horizontal direction HD2 of the tenth opening OP10′ may be smaller than the dimension in the second horizontal direction HD2 of the third chip overlapping region COR3. The dimension in the second horizontal direction HD2 of the tenth opening OP10′ may be smaller than the dimension in the second horizontal direction HD2 of the third semiconductor chip 23. The dimension in the second horizontal direction HD2 of the tenth opening OP10′ may be smaller than the dimension in the second horizontal direction HD2 of the first opening OP1′. The dimension in the second horizontal direction HD2 of the tenth opening OP10′ may be substantially the same as the dimension in the second horizontal direction HD2 of the second opening OP2′ and the dimension in the second horizontal direction HD2 of the third opening OP3′.

The eleventh opening OP11′ exposes a region including the fourteenth boundary B14 of the fourth chip overlapping region COR4. The eleventh opening OP11′ may expose an edge section of the fourth chip overlapping region COR4 including the fourteenth boundary B14 of the fourth chip overlapping region COR4, and the peripheral region PR that abuts the edge section. The eleventh opening OP11′ vertically overlaps the fourth semiconductor chip 24. The eleventh opening OP11′ vertically overlaps the fourteenth side surface S14 of the fourth semiconductor chip 24. As illustrated in FIG. 14, the eleventh opening OP11′ overlaps the fourth semiconductor chip 24 by a fourteenth width OL14′ in the first horizontal direction HD1. The fourteenth width OL14′ may have a size of 20 μm or more.

The eleventh opening OP11′ may be configured such that the dimension thereof in the second horizontal direction HD2 has a size larger than the dimension thereof in the first horizontal direction HD1. The dimension in the second horizontal direction HD2 of the eleventh opening OP11′ may be smaller than the dimension in the second horizontal direction HD2 of the fourth chip overlapping region COR4. The dimension in the second horizontal direction HD2 of the eleventh opening OP11′ may be smaller than the dimension in the second horizontal direction HD2 of the fourth semiconductor chip 24. The dimension in the second horizontal direction HD2 of the eleventh opening OP11′ may be smaller than the dimension in the second horizontal direction HD2 of the first opening OP1′. The dimension in the second horizontal direction HD2 of the eleventh opening OP11′ may be substantially the same size as the dimension in the second horizontal direction HD2 of the tenth opening OP10′.

The twelfth opening OP12′ may expose a region including the twelfth boundary B12 of the third chip overlapping region COR3. The twelfth opening OP12′ may expose an edge section of the third chip overlapping region COR3 including the twelfth boundary B12 of the third chip overlapping region COR3, and the peripheral region PR that abuts the edge section. The twelfth opening OP12′ vertically overlaps the third semiconductor chip 23. The twelfth opening OP12′ vertically overlaps the twelfth side surface S12 of the third semiconductor chip 23. As illustrated in FIG. 15 and FIG. 16, the twelfth opening OP12′ overlaps the third semiconductor chip 23 by a twelfth width OL12′ in the second horizontal direction HD2. The twelfth width OL12′ may have a size of 20 μm or more.

The twelfth opening OP12′ may be configured such that the dimension thereof in the first horizontal direction HD1 has a size larger than the dimension thereof in the second horizontal direction HD2. The dimension in the first horizontal direction HD1 of the twelfth opening OP12′ may be smaller than the dimension in the first horizontal direction HD1 of the third chip overlapping region COR3. The dimension in the first horizontal direction HD1 of the twelfth opening OP12′ may be smaller than the dimension in the first horizontal direction HD1 of the third semiconductor chip 23. The twelfth opening OP12′ may be connected to the first opening OP1′. The twelfth opening OP12′ may intersect with the first opening OP1′. The twelfth opening OP12′ may be configured integrally with the first opening OP1′.

The thirteenth opening OP13′ may expose a region including the sixteenth boundary B16 of the fourth chip overlapping region COR4. The thirteenth opening OP13′ may expose an edge section of the fourth chip overlapping region COR4 including the sixteenth boundary B16 of the fourth chip overlapping region COR4, and the peripheral region PR that abuts the edge section. The thirteenth opening OP13′ vertically overlaps the fourth semiconductor chip 24. The thirteenth opening OP13′ vertically overlaps the sixteenth side surface S16 of the fourth semiconductor chip 24. As illustrated in FIG. 17 and FIG. 18, the thirteenth opening OP13′ overlaps the fourth semiconductor chip 24 by a sixteenth width OL16′ in the second horizontal direction HD2. The sixteenth width OL16′ may have a size of 20 μm or more.

The thirteenth opening OP13′ may be configured such that the dimension thereof in the first horizontal direction HD1 has a size larger than the dimension thereof in the second horizontal direction HD2. The dimension in the first horizontal direction HD1 of the thirteenth opening OP13′ may be smaller than the dimension in the first horizontal direction HD1 of the fourth chip overlapping region COR4. The dimension in the first horizontal direction HD1 of the thirteenth opening OP13′ may be smaller than the dimension in the first horizontal direction HD1 of the fourth semiconductor chip 24. The thirteenth opening OP13′ may be connected to the first opening OP1′. The thirteenth opening OP13′ may intersect with the first opening OP1′. The thirteenth opening OP13′ may be configured integrally with the first opening OP1′.

The fourteenth opening OP14′ may expose the third bump bonding pads 12C. The fourteenth opening OP14′ may be configured to expose the plurality of third bump bonding pads 12C all at once. As illustrated in FIG. 11, the fourteenth opening OP14′ may be an H shape to expose, all at once, the third bump bonding pads 12C disposed in two columns in the second horizontal direction HD2. In correspondence to the arrangement structure of the third bump bonding pads 12C disposed in two columns in the second horizontal direction HD2, the fourteenth opening OP14′ of the H shape may be configured in the first insulating layer 15′. The fourteenth opening OP14′ intersects with a third through hole TH3′ to be described later. The third bumps BM3 may be bonded to the third bump bonding pads 12C exposed by the fourteenth opening OP14′. The third semiconductor chip 23 may be electrically connected to the third bump bonding pads 12C through the third bumps BM3. The fourteenth opening OP14′ may be connected to the fifth opening OP5′ and the twelfth opening OP12′. The fourteenth opening OP14′ may intersect with the fifth opening OP5′ and the twelfth opening OP12′. The fourteenth opening OP14′ may be configured integrally with the fifth opening OP5′ and the twelfth opening OP12′.

The fifteenth opening OP15′ may expose the fourth bump bonding pads 12D. The fifteenth opening OP15′ may be configured to expose the plurality of fourth bump bonding pads 12D all at once. As illustrated in FIG. 11, the fifteenth opening OP15′ may be an H shape to expose, all at once, the fourth bump bonding pads 12D disposed in two columns in the second horizontal direction HD2. In correspondence to the arrangement structure of the fourth bump bonding pads 12D disposed in two columns in the second horizontal direction HD2, the fifteenth opening OP15′ of the H shape may be configured in the first insulating layer 15′. The fifteenth opening OP15′ intersects with a fourth through hole TH4′ to be described later. The fourth bumps BM4 may be bonded to the fourth bump bonding pads 12D exposed by the fifteenth opening OP15′. The fourth semiconductor chip 24 may be electrically connected to the fourth bump bonding pads 12D through the fourth bumps BM4. The fifteenth opening OP15′ may be connected to the seventh opening OP7′ and the thirteenth opening OP13′. The fifteenth opening OP15′ may intersect with the seventh opening OP7′ and the thirteenth opening OP13′. The fifteenth opening OP15′ may be configured integrally with the seventh opening OP7′ and the thirteenth opening OP13′.

The first metal patterns 13B are disposed on the top surface 11T′ of the body layer 11′. Some of the first metal patterns 13B may be exposed through the first to seventh openings OP1′ to OP7′ and the tenth to thirteenth openings OP10′ to OP13′. Some of the first metal patterns 13B may be exposed through the first to seventh openings OP1′ to OP7′ and the tenth to thirteenth openings OP10′ to OP13′, and the other some may be covered with the first insulating layer 15′.

The first metal patterns 13B may have a plate shape. The first metal patterns 13B exposed through the first to seventh openings OP1′ to OP7′ and the tenth to thirteenth openings OP10′ to OP13′ may have a mesh structure that includes a plurality of holes MH. The first metal patterns 13B may be continuous in regions where the first to seventh openings OP1′ to OP7′ and the tenth to thirteenth openings OP10′ to OP13′ are disposed. Therefore, the first metal patterns 13B may electrically connect both sides of the regions where the first to seventh openings OP1′ to OP7′ and the tenth to thirteenth openings OP10′ to OP13′ are disposed. The first metal patterns 13B that are exposed through the first opening OP1′ may electrically connect the first chip overlapping region COR1 and the second chip overlapping region COR2, and may electrically connect the third chip overlapping region COR3 and the fourth chip overlapping region COR4. The first metal patterns 13B that are exposed through the second opening OP2′ may electrically connect the peripheral region PR and the first chip overlapping region COR1. The first metal patterns 13B that are exposed through the third opening OP3′ may electrically connect the peripheral region PR and the second chip overlapping region COR2. The first metal patterns 13B that are exposed through the fourth opening OP4′ may electrically connect the peripheral region PR and the first chip overlapping region COR1. The first metal patterns 13B that are exposed through the fifth opening OP5′ may electrically connect the first chip overlapping region COR1 and the third chip overlapping region COR3. The first metal patterns 13B that are exposed through the sixth opening OP6′ may electrically connect the peripheral region PR and the second chip overlapping region COR2. The first metal patterns 13B that are exposed through the seventh opening OP7′ may electrically connect the second chip overlapping region COR2 and the fourth overlapping region COR4. The first metal patterns 13B that are exposed through the tenth opening OP10′ may electrically connect the peripheral region PR and the third chip overlapping region COR3. The first metal patterns 13B that are exposed through the eleventh opening OP11′ may electrically connect the peripheral region PR and the fourth chip overlapping region COR4. The first metal patterns 13B that are exposed through the twelfth opening OP12′ may electrically connect the peripheral region PR and the third chip overlapping region COR3. The first metal patterns 13B that are exposed through the thirteenth opening OP13′ may electrically connect the peripheral region PR and the fourth chip overlapping region COR4.

The molding layer 30′ may be filled in the holes MH of the first metal patterns 13B having the mesh shape in the first to seventh openings OP1′ to OP7′ and the tenth to thirteenth openings OP10′ to OP13′. In an embodiment, the first metal patterns 13B may be ground patterns. In another embodiment, the first metal patterns 13B may be power patterns. Only one type of first metal patterns 13B may be exposed in each of the first to seventh openings OP1′ to OP7′ and the tenth to thirteenth openings OP10′ to OP13′. For example, only ground patterns or only power patterns may be exposed through the first opening OP1′. Ground patterns and power patterns are exposed not simultaneously through the first opening OP1′. Although the present embodiment illustrates that the first metal patterns 13B are exposed through all of the first to seventh openings OP1′ to OP7′ and the tenth to thirteenth openings OP10′ to OP13′, the present disclosure is not limited thereto. The first metal patterns 13B may be exposed through at least one of the first to seventh openings OP1′ to OP7′ and the tenth to thirteenth openings OP10′ to OP13′. Meanwhile, the first metal patterns 13B might not be exposed through the first to seventh openings OP1′ to OP7′ and the tenth to thirteenth openings OP10′ to OP13′.

The second metal patterns 14′ may be disposed on a bottom surface 11B′ of the body layer 11′. Some of the second metal patterns 14′may include ball lands 14A′. The second insulating layer 16′ is disposed on the bottom surface 11B′ of the body layer 11′, and may have openings that expose the ball lands 14A′. The external connection terminals 40′ may be attached to the ball lands 14A′. The external connection terminal 40′ may include solder balls.

The first, second, third and fourth through holes TH1′, TH2′, TH3′ and TH4′ that pass through the package substrate 10C including the body layer 11′ and the second insulating layer 16′ are configured. The first through hole TH1′ vertically passes through the package substrate 10C in the first chip overlapping region COR1. The second through hole TH2′ vertically passes through the package substrate 10C in the second chip overlapping region COR2. The third through hole TH3′ vertically passes through the package substrate 10C in the third chip overlapping region COR3. The fourth through hole TH4′ vertically passes through the package substrate 10C in the fourth chip overlapping region COR4. In a process of forming the molding layer 30′, air may be discharged through the first, second, third and fourth through holes TH1′, TH2′, TH3′ and TH4′. The first, second, third and fourth through holes TH1′, TH2′, TH3′ and TH4′ may be vent holes for discharge of air. The first through hole TH1′ is exposed through the eighth opening OP8′. The first through hole TH1′ is connected to the eighth opening OP8′. The first through hole TH1′ intersects with the eighth opening OP8′. The second through hole TH2′ is exposed through the ninth opening OP9′. The second through hole TH2′ is connected to the ninth opening OP9′. The second through hole TH2′ intersects with the ninth opening OP9′. The third through hole TH3′ is exposed through the fourteenth opening OP14′. The third through hole TH3′ is connected to the fourteenth opening OP4′. The third through hole TH3′ intersects with the fourteenth opening OP4′. The fourth through hole TH4′ is exposed through the fifteenth opening OP15′. The fourth through hole TH4′ is connected to the fifteenth opening OP15′. The fourth through hole TH4′ intersects with the fifteenth opening OP15′.

The molding layer 30′may include a top molding section 31′, first, second, third and fourth extending sections 32A, 32B, 32C and 32D, and first and second bottom molding sections 33A, 33B. The molding layer 30′ may be formed by a molding process using a liquid molding material. The molding material may include an epoxy molding compound (EMC). The epoxy molding compound (EMC) may include resin and filler.

The top molding section 31′ fills the space between the first semiconductor chip 21 and the package substrate 10C, the space between the second semiconductor chip 22 and the package substrate 10C, the space between the third semiconductor chip 23 and the package substrate 10C and the space between the fourth semiconductor chip 24 and the package substrate 10C, and surrounds the first, second, third and fourth semiconductor chips 21, 22, 23 and 24 and the first, second, third and fourth bumps BM1, BM2, BM3 and BM4. During the molding process, vacuum evacuation may occur through the first, second, third and fourth through holes TH1′, TH2′, TH3′ and TH4′ of the package substrate 10C. By the difference between by a pressure with which the molding material is injected and the pressure due to vacuum evacuation through the first, second, third and fourth through holes TH1′, TH2′, TH3′ and TH4′, the molding material may flow into the space between the first semiconductor chip 21 and the package substrate 10C, the space between the second semiconductor chip 22 and the package substrate 10C, the space between the third semiconductor chip 23 and the package substrate and the space between the fourth semiconductor chip 24 and the package substrate 10C. Thus, the space between the first semiconductor chip 21 and the package substrate 10C, the space between the second semiconductor chip 22 and the package substrate 10C, the space between the third semiconductor chip 23 and the package substrate 10C and the space between the fourth semiconductor chip 24 and the package substrate 10C may be filled with the top molding section 31′.

The top molding section 31′ may surround the first, second, third and fourth semiconductor chips 21, 22, 23 and 24 and the first, second, third and fourth bumps BM1, BM2, BM3 and BM4 to protect them from an external environment. In the present embodiment, the top molding section 31′ covers the top surfaces of the first, second, third and fourth semiconductor chips 21, 22, 23 and 24. However, in another example, the top molding section 31′may expose the top surfaces of the first, second, third and fourth semiconductor chips 21, 22, 23 and 24.

Because passages through which the molding material is introduced are widened by the first to seventh openings OP1′ to OP7′ and the tenth to thirteenth openings OP10′ to OP13′, the flowability of the molding material that flows into the space between the first semiconductor chip 21 and the package substrate 10C, the space between the second semiconductor chip 22 and the package substrate 10C, the space between the third semiconductor chip 23 and the package substrate and the space between the fourth semiconductor chip 24 and the package substrate 10C may be improved. The first to fifteenth openings OP1′ to OP15′ are filled with the molding material. The top molding section 31′may extend to the first to fifteenth openings OP1′ to OP15′.

The molding material is introduced into the first, second, third and fourth through holes TH1′, TH2′, TH3′ and TH4′ during the molding process, and accordingly, the first extending section 32A that fills the first through hole TH1′, the second extending section 32B that fills the second through hole TH2′, the third extending section 32C that fills the third through hole TH3′ and the fourth extending section 32D that fills the fourth through hole TH4′ and the first and second bottom molding sections 33A and 33B that protrude on the bottom of the second insulating layer 16′may be formed. Each of the first and second bottom molding sections 33A and 33B may have a bar shape or line shape that extends in the first horizontal direction HD1.

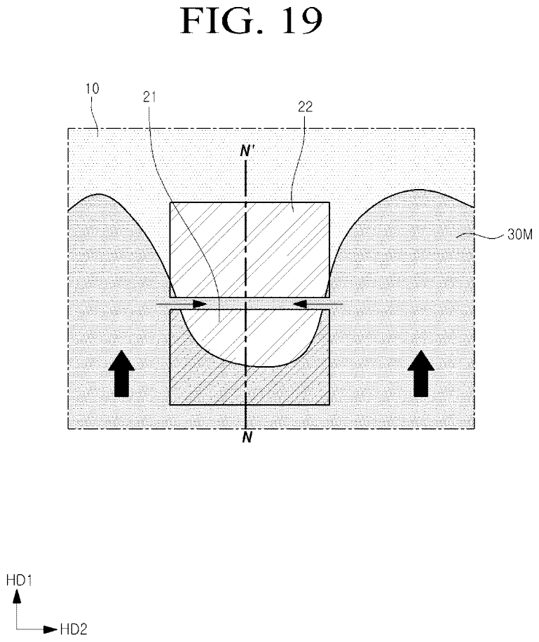

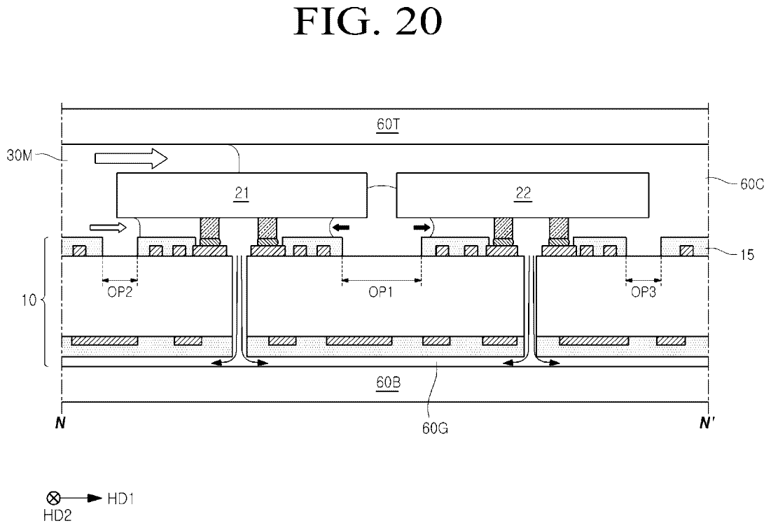

FIG. 19 and FIG. 20 are views showing the effects of a semiconductor package according to the present disclosure. FIG. 19 is a plan view illustrating a molded underfill process related with the present disclosure, and FIG. 20 is a cross-sectional view taken along a line N-N′ of FIG. 19.

Referring to FIG. 19 and FIG. 20, semiconductor chips 21 and 22 may be mounted on a package substrate 10, the package substrate 10 may be placed in molds 60T and 60B, and a molding material 30M may be injected into the molds 60T and 60B. The top mold 60T is disposed on the semiconductor chips 21 and 22, and a cavity 60C into which the molding material 30M is to be filled is defined between the package substrate 10 and the top mold 60T. The bottom mold 60B may have a molding groove 60G in which a bottom molding section is to be formed.

The molding material 30M may be an epoxy molding compound (EMC). The epoxy molding compound (EMC) includes resin and filler.

The molding material 30M flows in a liquid state, and in a region where the semiconductor chips 21 and 22 are mounted, the flow of the molding material 30M is resisted by the semiconductor chips 21 and 22, so that the flow speed of the molding material 30M decreases. As a result, a difference in the flow speed of the molding material 30M occurs between the region where the semiconductor chips 21 and 22 are mounted and a region where the semiconductor chips 21 and 22 are not mounted, and uniform flow of the molding material 30M becomes difficult, so that voids may be generated.

In order to maximize the heat dissipation characteristics of a package, it is advantageous to use the filler of an epoxy molding compound (EMC) with a large particle size to better secure a heat dissipation path for dissipating heat generated during driving of a chip and obtain high thermal conductivity. As the particle size of the filler increases, thermal conductivity increases and heat dissipation characteristics are improved. However, due to the characteristics of a molded underfill structure that requires the space between a semiconductor chip and a package substrate to be filled with a molding material, a bottleneck phenomenon may occur during a molding process due to the filler with a large particle size. Thus, as the molding material does not flow smoothly into the space between the semiconductor chip and the package substrate, voids may remain between the semiconductor chip and the package substrate.

According to an embodiment of the present disclosure, a first opening OP1 is configured in a first insulating layer 15 of the package substrate 10 to alleviate a bottleneck phenomenon of the molding material 30M due to the filler and increase the flow speed of the molding material 30M between the first semiconductor chip 21 and the second semiconductor chip 22, whereby it is possible to suppress voids from remaining under the first and second semiconductor chips 21 and 22. Second and third openings OP2 and OP3 may also contribute to improving the flow speed of the molding material 30M.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

1. A semiconductor package comprising:
a package substrate including a body layer and a first insulating layer that is disposed on the body layer;
a first semiconductor chip mounted on the package substrate by a first bump;
a second semiconductor chip mounted on the package substrate by a second bump; and
a molding layer filling the space between the package substrate and the first semiconductor chip and the space between the package substrate and the second semiconductor chip, and surrounding the first and second semiconductor chips,
wherein the body layer includes a first chip overlapping region that vertically overlaps the first semiconductor chip, a second chip overlapping region that vertically overlaps the second semiconductor chip and an intermediate region between the first chip overlapping region and the second chip overlapping region, and
wherein the first insulating layer includes a first opening that exposes the intermediate region, an edge section of the first chip overlapping region abutting the intermediate region and an edge section of the second chip overlapping region abutting the intermediate region.

2. The semiconductor package according to claim 1, wherein
the first semiconductor chip is disposed next to the second semiconductor chip in a first horizontal direction,
the dimension in a second horizontal direction of the first opening is larger than the dimension in the second horizontal direction of the first semiconductor chip,
the dimension in the second horizontal direction of the first opening is larger than the dimension in the second horizontal direction of the second semiconductor chip, and
wherein the first horizontal direction is perpendicular to the second horizontal direction.

3. The semiconductor package according to claim 1, wherein
the first opening overlaps the first semiconductor chip by a first width and overlaps the second semiconductor chip by a second width, and
each of the first width and the second width has a size of 20 μm or more.

4. The semiconductor package according to claim 1, wherein the first opening is filled with the molding layer.

5. The semiconductor package according to claim 1, wherein
the body layer further includes a peripheral region that surrounds the first and second chip overlapping regions and the intermediate region, and
the first insulating layer further includes a second opening that exposes a boundary of the first chip overlapping region abutting the peripheral region.

6. The semiconductor package according to claim 5, wherein the second opening is configured to expose an edge section of the first chip overlapping region and the peripheral region.

7. The semiconductor package according to claim 5, wherein
the first semiconductor chip is disposed next to the second semiconductor chip in a first horizontal direction,
the first chip overlapping region includes a first boundary that abuts the intermediate region and a second boundary that faces the first boundary in the first horizontal direction, and
the second opening exposes the second boundary.

8. The semiconductor package according to claim 7, wherein
the dimension in the second horizontal direction of the second opening is smaller than the dimension in the second horizontal direction of the first opening, and
the first horizontal direction is perpendicular to the second horizontal direction.

9. The semiconductor package according to claim 7, wherein the second opening is filled with the molding layer.

10. The semiconductor package according to claim 5, wherein
the first semiconductor chip is disposed next to the second semiconductor chip in a first horizontal direction,
the first chip overlapping region includes a first boundary and a second boundary that face each other in a second horizontal direction perpendicular to the first horizontal direction, and
the second opening exposes one of the first boundary and the second boundary.

11. The semiconductor package according to claim 10, wherein the second opening is connected to the first opening.

12. The semiconductor package according to claim 10, wherein
the package substrate further includes a bump bonding pad that is bonded with the first bump, and
the first insulating layer further includes a third opening that exposes the bump bonding pad.

13. The semiconductor package according to claim 12, wherein the third opening is filled with the molding layer.

14. The semiconductor package according to claim 12, wherein the third opening is connected to the second opening.

15. The semiconductor package according to claim 1, wherein the body layer further includes:
a first through hole that passes through the first chip overlapping region; and
a second through hole that passes through the second chip overlapping region.

16. The semiconductor package according to claim 15, wherein the molding layer includes:
a first extending section that fills the first through hole; and
a second extending section that fills the second through hole.

17. The semiconductor package according to claim 16, further comprising
a second insulating layer disposed on a bottom surface of the body layer,
wherein the first insulating layer is disposed on a top surface of the body layer,
wherein the molding layer further includes a bottom molding section disposed under the second insulating layer and connected to the first and second extending sections.

18. The semiconductor package according to claim 17, wherein
the first semiconductor chip is disposed next to the second semiconductor chip in a first horizontal direction, and
the bottom molding section extends in a second horizontal direction perpendicular to the first horizontal direction.

19. The semiconductor package according to claim 12, further comprising
first metal patterns disposed on the body layer,
wherein some of the first metal patterns are exposed through at least one of the first opening, the second opening and the third opening.

20. The semiconductor package according to claim 19, wherein the first metal patterns have a mesh structure that includes a plurality of holes.

21. The semiconductor package according to claim 20, wherein the plurality of holes are filled with the molding layer.

22. The semiconductor package according to claim 19, wherein the first metal patterns include ground patterns or power patterns.
